(19) United States
(12) Patent Application Publication
(10) Pub. No.: US 2011/0254578 A1
(43) Pub. Date: Oct. 20, 2011

(54) SPACE TRANSFORMER COMPRISING AN ISOLATION RESISTOR FOR A PROBE CARD, AND METHOD FOR MANUFACTURING SAME

(76) Inventors: Min Soo Kim, Gyeonggido (KR); Sung Man Yoon, Gyeonggido (KR)

(21) Appl. No.: 13/121,826

(22) PCT Filed: Sep. 24, 2009
(86) PCT No.: PCT/KR2009/005441

§ 371 Date: Jul. 6, 2011

(30) Foreign Application Priority Data
Sep. 30, 2008 (KR) 1020080096085

(51) Int. Cl. G01R 31/00; H01F 41/00

(52) U.S. Cl. 324/756.03; 29/602.1

(57) ABSTRACT

The invention provides a space transformer for a probe card including an isolation resistor for isolating electrical effects between adjacent channels to perform tests on a plurality of devices under test (DUTs) formed on a wafer at one time, the space transformer including: a plurality of ceramic layers on which circuits for testing the DUTs are printed and which are stacked on one another; an isolation resistor disposed between the ceramic layers and formed by printing a resistance material so as not to be exposed to the outside. The invention also provides a method of manufacturing a space transformer for a probe card including an isolation resistor for isolating electrical effects between adjacent channels to perform tests on a plurality of devices under test (DUTs) formed on a wafer at one time, the method including the steps of: printing a resistance material to form the isolation resistor in a ceramic sheet; stacking a ceramic sheet on the ceramic sheet on which the resistance material is printed such that the resistance material is disposed between the ceramic sheets; and sintering the stacked ceramic sheets.

### TECHNICAL FIELD

The present invention relates to a space transformer for a probe card, and more particularly to a probe card used to test a semiconductor integrated circuit, a space transformer used in the probe card, and a method of manufacturing the space transformer.

### BACKGROUND ART

In general, integrated circuits manufactured through semiconductor processes are very complex, has a variety of and a number of electrodes.

After such an integrated circuit is completely manufactured, an electrical characteristic and a fault of the integrated circuit are tested. A probe card is used to test an electrical characteristic of such an integrated circuit.

Such a probe card connects a circuit tester and an integrated circuit to enable testing of the circuit.

A probe card typically includes a substrate, a space transformer, and a probe. The probe is installed in the space transformer to directly contact the circuit, and the space transformer electrically connects the substrate and the probe.

The space transformer is disposed in a space between the substrate and the probe, and serves to support the substrate and the probe with respect to a space between a test device and the integrated circuit, i.e. a target to be tested.

In recent years, degrees of integration of integrated circuits on wafers which are to be tested using probe cards are increasing, and the sizes of wafers to be tested at once are also increasing.

Conventionally, a probe are touched down for each device under test (DUT) which is a semiconductor device on a wafer to test the DUT, but it is time consuming to test the DUT, lowering productivity.

In order to solve this problem, a plurality of sets of DUTs such as two sets, four sets, or eight sets of DUTS are tested by touching down a probe once to shorten a test time.

When a plurality of DUTs are simultaneously tested using a probe card, a plurality of isolation resistors 3 are installed on the bottom surface of a space transformer 1 as illustrated in FIG. 1 so that electrical instability of a DUT due to its fault cannot influence another test channel.

The isolation resistors are formed by bonding resistance devices on pads 2 provided on the bottom surface of the space transformer 1, or by printing or depositing a resistance body.

Meanwhile, if the space transformer 1 is etched for a long time in the process of installing a probe pin on the bottom surface of the space transformer 1, the isolation resistors 3 formed in advance are damaged, causing electrical characteristics of the isolation resistors 3 to be changed or lost.

Also, it is difficult in design to dispose a plurality of isolation resistors 3 between a plurality of probe pins to be attached to the bottom surface of the space transformer 1. In particular, as degrees of integration of semiconductor devices under test are recently increasing, it becomes more difficult to suitably dispose an isolation resistor on the bottom surface of a space transformer.

### DISCLOSURE

### Technical Problem

Therefore, the present invention has been made in view of the above-mentioned problems, and the present invention provides a space transformer that prevents an isolation resistor from being damaged in the process of forming a probe pin.

The present invention also provides a space transformer that easily secures a space for disposing isolation resistors in designing a space transformer for a probe card for testing semiconductor devices of high degrees of integration.

### Technical Solution

In accordance with an aspect of the present invention, there is provided a method of manufacturing a space transformer for a probe card including an isolation resistor for isolating electrical effects between adjacent channels to perform tests on a plurality of devices under test (DUTs) formed on a wafer at one time the method including the steps of: printing a resistance material to form the isolation resistor in a ceramic sheet; stacking a ceramic sheet on the ceramic sheet on which the resistance material is printed such that the resistance material is disposed between the ceramic sheets; and sintering the stacked ceramic sheets.

In accordance with another aspect of the present invention, there is provided a method of manufacturing a space transformer for a probe card including an isolation resistor for isolating electrical effects between adjacent channels to perform tests on a plurality of devices under test (DUTs) formed on a wafer at one time, the method including the steps of: punching via holes for forming the isolation resistor in a ceramic sheet; filling a resistance material in the punched via holes of the ceramic sheet; stacking a plurality of ceramic sheets including the ceramic sheet in which the resistance material is filled; and sintering the stacked ceramic sheets.

In accordance with a further aspect of the present invention, there is provided a space transformer for a probe card including an isolation resistor for isolating electrical effects between adjacent channels to perform tests on a plurality of devices under test (DUTs) formed on a wafer at one time, the space transformer including: a plurality of ceramic layers on which circuits for testing the DUTs are printed and which are stacked on one another; an isolation resistor disposed between the ceramic layers and formed by printing a resistance material so as not to be exposed to the outside.

In accordance with still another embodiment of the present invention, there is provided a space transformer for a probe card including an isolation resistor for isolating electrical effects between adjacent channels to perform tests on a plurality of devices under test (DUTs) formed on a wafer at one time, the space transformer including: a plurality of ceramic layers on which circuits for testing the DUTs are printed and which are stacked on one another; and at least one via isolation resistor formed by filling a resistance material in via holes passing through the ceramic layer.

### BRIEF DESCRIPTION OF THE DRAWINGS

The foregoing and other objects, features and advantages of the present invention will become more apparent from the following detailed description when taken in conjunction with the accompanying drawings in which:

FIG. 1 is a sectional view illustrating a portion of a conventional space transformer for a probe card; and

FIG. 2 is a sectional view illustrating a space transformer for a probe card according to an embodiment of the present invention.

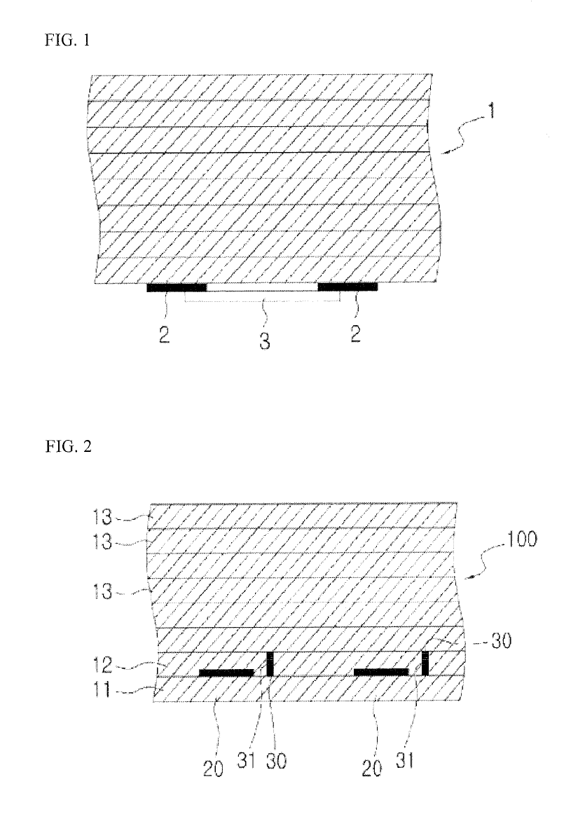

### BEST MODE

### Mode for Invention

Hereinafter, exemplary embodiments of the present invention will be described with reference to the accompanying drawings.

First, a method of manufacturing a space transformer for a probe card including an isolation resistor according to an embodiment of the present invention will be described.

FIG. 2 is a sectional view illustrating a portion of a portion of a space transformer for a probe card according to an embodiment of the present invention.

Generally, a method of manufacturing a space transformer for a probe card is as follows.

A via hole is punched in a ceramic sheet and a conductive material is filled in the via hole. A circuit is printed in the ceramic sheet, and a plurality of ceramic sheets are stacked and sintered. This process is also applied to a method of manufacturing a space transformer for a probe card including an isolation resistor according to the embodiment of the present invention.

The features of the method of manufacturing a space transformer for a probe card including an isolation resistor according to an embodiment of the present invention are as follows.

First, when via holes 31 are punched in ceramic sheets 11, 12, and 13, a via hole 31 for forming an isolation resistor 20 is also punched in a via hole forming step.

Next, a resistance material is filled in the punched via holes 31 in a resistance material filling step.

The resistance material is sintered together with the ceramic sheets 11, 12, and 13 to serve as an isolation resistor in the space transformer 100. The isolation resistor formed as such is called a via isolation resistor 30 hereinbelow.

The resistance of the via isolation resistor 30 may be easily regulated to various values by adjusting the diameter of the via hole 31.

The resistance may be regulated by providing a plurality of via isolation resistors 30 and connecting the via isolation resistors in parallel. When the via holes 31 are punched, the diameters of the via holes 31 may be dispersed, causing the resistances of the via isolation resistances 30 to be varied. Then, if the plurality of via isolation resistors 30 are connected in parallel to regulate the resistance, the dispersion of the diameters of the via holes 31 influences the resistance of the via isolation resistors 30 less, making it possible to regulate the resistance more accurately.

When a space transformer is manufactured by using an LTCC ceramic sheet, the material of the resistors may be Ru-based (RuO₂, Bi₂Ru₂O₇, Pb₂Ru₂O₆), Pd/Ag-based, or LaB₆-based paste, and when a space transformer is manufactured by using HTCC ceramic sheet, the material of the resistors may be W, Mo, MoS₁₂, etc. Meanwhile, when circuits for testing a semiconductor device are printed in the ceramic sheets 11, 12, and 13, a resistance material is printed in the ceramic sheets 11, 12, and 13 to form isolation resistors 20 in a resistance material printing step.

Similar to the resistors 30 formed in the via holes 31, the resistors 20 printed in the ceramic sheets 11, 12, and 13 also serve as isolation resistors of the space transformer 100.

After the ceramic sheets 13 are all stacked on the ceramic sheet 12 where the via holes 31 are filled with the resistance material and the ceramic sheet 11 on which the resistance material is printed, the stacked ceramic sheets 11, 12, and 13 are sintered to finish the space transformer 100 in a sintering step.

Meanwhile, the ceramic sheets 11, 12, and 13 may be preferably stacked such that the resistors 20 are disposed between the lowermost ceramic sheet 11 and the ceramic sheet 12 adjacent to the ceramic sheet 11 of the space transformer 100.

The isolation resistors 20 may be preferably situated near the probe pin to be installed at a lower portion of the space transformer 100 to improve electrical characteristics of the space transformer 100 and effectively protect and isolate adjacent channels from electrical impacts.

For the same reason, the ceramic sheets 11, 12, and 13 may be preferably stacked to manufacture the space transformer 100 such that the via isolation resistors 30 are formed in the ceramic sheet 11 situated at the lower portion of the space transformer 100 or in the ceramic sheet 12 adjacent to the ceramic sheet 11.

Hereinafter, an example of a space transformer for a probe card including an isolation resistor manufactured through the above-described method will be described.

The space transformer for a probe card according to an embodiment of the present invention includes a plurality of stacked ceramic layers 11, 12, and 13 on which circuits for testing a DUT.

An isolation resistor 20 disposed between the ceramic layers and formed by printing a resistance material is disposed in one 11 of the ceramic layers 11, 12, and 13 so as not to be exposed to the outside

A via isolation resistor 30 formed by filling a resistance material in a via hole 31 passing through one 12 of the ceramic layers 11, 12, and 13 is formed in the ceramic layer 12.

The isolation resistor 20 may be preferably disposed between the ceramic layer 11 situated at the lowermost portion of the space transformer 100 and the ceramic layer 12 adjacent to the ceramic layer 11.

The via isolation resistor 30 may be preferably located in the ceramic layer 11 situated at the lowermost portion of the space transformer 100 and the ceramic layer 12 adjacent to the ceramic layer 11.

In the space transformer for a probe card according to the embodiment of the present invention, since the isolation resistors 20 and the via isolation resistors 30 are not exposed to the outside of the space transformer but disposed within or between the ceramic layers 11, 12, and 13, there is little possibility of their being damaged or broken. That is, MEMS processes including a long time etching step are occasionally performed on a bottom surface of the space transformer 100 to install a probe pin in the space transformer 100, in which case the isolation resistors 20 and the via isolation resistors 30 are not exposed because they are located within the space transformer 100. Thus, even if an MEMS process including an etching step is performed on the bottom surface of the space transformer 100, characteristics of the isolation resistors 20 and the via isolation resistors 30 are not influenced, making it possible to improve the quality of the space transformer 100 and the productivity of the manufacturing process.

Also, since the isolation resistors 20 and the via isolation resistors 30 are not located on the bottom surface of the space transformer 100 but within the space transformer 100, a probe pin can be easily disposed in and detached from the space transformer 100. Furthermore, when a semiconductor device of a very high degree of integration is tested, a space for disposing probe pins densely can be easily secured as compared with a conventional one.

Although a space transformer and a method of manufacturing the same according to the exemplary embodiments of the present invention have been described until now, a space transformer and a method of manufacturing the same according to the present invention are not limited to the embodiment describe with reference to the drawings.

For example, although a space transformer 100 including both an isolation resistor 20 and a via isolation resistor 30 has been exemplified, a space transformer having any one of the isolation resistor 20 and the via isolation resistor 30 may be manufactured.

Furthermore, a space transformer may be configured such that the isolation resistor 20 is located other than between the ceramic layer situated at the lowermost ceramic layer of the space transformer and the ceramic layer adjacent to it.

### INDUSTRIAL APPLICABILITY

According to a space transformer and a method of manufacturing the space transformer of the present invention, since an isolation resistor is not damaged during its manufacturing process, making it possible to improve the quality and yield rate of the space transformer.

In addition, according to a space transformer and a method of manufacturing the space transformer of the present invention, since a space for disposing isolation resistors is easily secured, the space transformer can be easily designed.

1. A method of manufacturing a space transformer for a probe card including an isolation resistor for isolating electrical effects between adjacent channels to perform tests on a plurality of devices under test (DUTs) formed on a wafer at one time, the method comprising the steps of:
printing a resistance material to form the isolation resistor on a ceramic sheet;
stacking another ceramic sheet on the ceramic sheet on which the resistance material is printed such that the resistance material is disposed between the ceramic sheets; and
sintering the stacked ceramic sheets.

2. The method as claimed in claim 1, further comprising the steps of:
punching via holes for forming the isolation resistor in the ceramic sheet; and
filling the resistance material in the punched via holes of the ceramic sheet.

3. The method as claimed in claim 2, wherein some of via isolation resistors formed through the via hole punching step and the resistance material filling step are connected in parallel to each other.

4. The method as claimed in claim 1, wherein the ceramic sheets are stacked such that the resistance material is disposed between the ceramic sheet located at a lowermost portion of the space transformer and the ceramic sheet adjacent to the lowermost ceramic sheet.

5. A method of manufacturing a space transformer for a probe card including an isolation resistor for isolating electrical effects between adjacent channels to perform tests on a plurality of devices under test (DUTs) formed on a wafer at one time, the method comprising the steps of:
punching via holes for forming the isolation resistor in a ceramic sheet;
filling a resistance material in the punched via holes of the ceramic sheet;
stacking a plurality of ceramic sheets including the ceramic sheet in which the resistance material is filled; and
sintering the stacked ceramic sheets.

6. The method as claimed in claim 5, wherein some of via isolation resistors formed through the via hole punching step and the resistance material filling step are connected in parallel to each other.

7. A space transformer for a probe card including an isolation resistor for isolating electrical effects between adjacent channels to perform tests on a plurality of devices under test (DUTs) formed on a wafer at one time, the space transformer comprising:
a plurality of ceramic layers on which circuits for testing the DUTs are printed and which are stacked on one another;
an isolation resistor disposed between the ceramic layers and formed by printing a resistance material so as not to be exposed to the outside.

8. The space transformer as claimed in claim 7, further comprising:
at least one via isolation resistor formed by filling the resistance material in a via hole passing through the ceramic layer.

9. The space transformer as claimed in claim 8, wherein a plurality of via isolation resistors are provided such that some of the via isolation resistors are connected in parallel to each other.

10. The space transformer as claimed in claim 7, wherein the resistance material is disposed between the ceramic sheet located at a lowermost portion of the space transformer and the ceramic sheet adjacent to the lowermost ceramic sheet.

11. A space transformer for a probe card including an isolation resistor for isolating electrical effects between adjacent channels to perform tests on a plurality of devices under test (DUTs) formed on a wafer at one time, the space transformer comprising:
a plurality of ceramic layers on which circuits for testing the DUTs are printed and which are stacked on one another; and
at least one via isolation resistor formed by filling a resistance material in via holes passing through the ceramic layer.

12. The space transformer as claimed in claim 11, wherein a plurality of via isolation resistors are provided such that some of the via isolation resistors are connected in parallel to each other.
